(19) United States
(12) Patent Application Publication
(10) Pub. No.: US 2026/0022976 A1
(43) Pub. Date: Jan. 22, 2026

(54) METHOD AND DEVICE FOR ESTIMATING TEMPERATURE OF HEATED OBJECT

(71) Applicant: LIVSMED INC., Seongnam-si (KR)

(72) Inventor: Ik Jae JANG, Seongnam-si (KR)

(21) Appl. No.: 18/940,144

(22) Filed: Nov. 7, 2024

(30) Foreign Application Priority Data
Jul. 22, 2024 (KR) 10-2024-0096261

(51) Int. Cl. G01K 7/00; H05B 3/22

(52) U.S. Cl. CPC G01K 7/00; H05B 3/22

(57) ABSTRACT

Provided are a method and device for supplying power to a heating element. A method of estimating a temperature of a heated object includes: supplying power to a heating element for a predetermined period of time, the heating element being configured for contacting an object and for joule heating; obtaining momentary current values corresponding to the power at two or more respective points of time from a plurality of points of time included in the predetermined period of time; determining a characteristic of the object using at least one of the momentary current values; and estimating a temperature of the object based on a parameter calculated based on the momentary current values and the characteristic.

### CROSS-REFERENCE TO RELATED APPLICATION

This application is based on and claims priority under 35 U.S.C. § 119 to Korean Patent Application No. 10-2024-0096261, filed on Jul. 22, 2024, in the Korean Intellectual Property Office, the disclosure of which is incorporated by reference herein in its entirety.

### BACKGROUND

### 1. Field

The present disclosure relates to a method and device for estimating the temperature of a heated object and, more particularly, to a method and device for indirectly controlling the temperature of a heating element by using a change in current of the heating element depending on a moisture content.

### 2. Description of the Related Art

Temperature control is critical when using a heating element to remove moisture from an object. Setting an appropriate temperature may allow to only moisture to be effectively removed while maintaining the physical or chemical properties of the object; however, setting an inappropriate temperature may result in failure to completely remove moisture from the object or result in changes to the physical or chemical properties of the object. Therefore, how to estimate the temperature of a heated object is an issue.

On the other hand, to remove moisture from an object using a heating element, a feedback control system may be used that monitors and adjusts the temperature in real time using a temperature sensor and a control system to adjust the temperature of the object so that the temperature does not fall outside of a set range, but there is a problem of low usability because a separate temperature sensor is required.

The above background technology is technical information that the inventor(s) possessed for conceiving the present disclosure or acquired in the process of conceiving the present disclosure, and should not be considered prior art already known to the public prior to the filing of the present disclosure.

### SUMMARY

The present disclosure is directed to provide a method and device for estimating the temperature of a heated object. The objective of the present disclosure is not limited to the above-described description, and other objectives and advantages not explicitly disclosed herein will be clearly understood from the following description, and will be understood more clearly according to embodiments of the present disclosure. It will also be appreciated that the above and other objectives and advantages of the present disclosure may be realized by means disclosed in the claims and combinations thereof.

Additional aspects will be set forth in part in the description which follows and, in part, will be apparent from the description, or may be learned by practice of the presented embodiments of the disclosure.

According to a first aspect of the present disclosure, a method of estimating a temperature of a heated object includes: supplying power to a heating element for a predetermined period of time, the heating element being configured for contacting an object and for joule heating; obtaining momentary current values corresponding to the power at two or more respective points of time from a plurality of points of time included in the predetermined period of time; determining a characteristic of the object using at least one of the momentary current values; and estimating a temperature of the object based on a parameter calculated based on the momentary current values and the characteristic.

In an embodiment, the determining may include determining a moisture state of the object at one or more points of time included in the predetermined period of time based on the parameter calculated based on the momentary current values.

In an embodiment, the moisture state may include at least one state occurring during a process of removing moisture contained in the object for the predetermined period of time.

In an embodiment, the at least one state may include at least one of a first state in which a temperature of moisture contained in the object increases, a second state in which the moisture evaporates, and a third state in which the temperature of the moisture increases, and a first rate of change of the temperature of the moisture in the first state may be greater than a second rate of change of the temperature of the moisture in the third state.

In an embodiment, the determining may include determining the moisture state to be the first state based on a result of comparing the parameter to a first threshold value.

In an embodiment, the determining may include determining the moisture state to be the second state based on a result of comparing the parameter to a first threshold value and a second threshold value, and the second threshold value may be smaller than the first threshold value.

In an embodiment, the determining may include determining the moisture state to be the third state based on a result of comparing the parameter to a second threshold value.

In an embodiment, the second state may include a plurality of substates divided based on a residual moisture content of the object predicted based on the parameter.

In an embodiment, the heating element may be heated in an open loop manner where the power is controlled based on the momentary current values.

In an embodiment, the determining may include predicting a thickness of the object based on an initial value of the momentary current values.

In an embodiment, the predicting may include estimating a temperature of the object based on a temperature profile corresponding to the thickness of the object and the parameter.

In an embodiment, the momentary current values may be obtained using a current sensor disposed on an electrical wire electrically connecting a power board configured to supply the power and the heating element to each other.

According to a second aspect of the present disclosure, a device for estimating a temperature of a heated object includes: a memory having at least one program stored therein; and a processor configured to perform calculation by executing the at least one program, wherein the processor is configured to supply power to a heating element for a predetermined period of time, the heating element being configured for contacting an object and for joule heating, obtain momentary current values corresponding to the power at two or more respective points of time from a plurality of points of time included in the predetermined period of time, determine a characteristic of the object using at least one of the momentary current values, and estimate a temperature of the object based on a parameter calculated based on the momentary current values and the characteristic.

A third aspect of the present disclosure may provide a computer-readable recording medium having recorded thereon a program to cause the method of the first aspect to be executed on a computer.

In addition, other methods and other devices for implementing the present disclosure and other computer-readable recording media having recorded thereon programs for causing the methods to be executed on a computer may be provided.

Other aspects, features, and advantages in addition to those described above will become apparent from the following drawings, the claims, and the detailed description of the present disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are diagrams illustrating an example of an environment for estimating the temperature of a heated object according to an embodiment of the present disclosure;

FIG. 3 is a flowchart illustrating a method of estimating the temperature of a heated object according to an embodiment of the present disclosure;

FIG. 4 is an example diagram illustrating an object in contact with a heating element according to an embodiment of the present disclosure;

FIGS. 5A to 5C are diagrams illustrating a moisture state of an object according to an embodiment of the present disclosure;

FIG. 6 is a diagram illustrating a current slope according to an embodiment of the present disclosure;

FIG. 7 is a diagram illustrating a plurality of substates according to an embodiment of the present disclosure;

FIG. 8 is a diagram illustrating a current slope and an estimated temperature according to an embodiment of the present disclosure;

FIG. 9 is a diagram illustrating a method of selecting a standard profile according to an embodiment of the present disclosure;

FIG. 10 is a diagram illustrating a method of controlling power based on a standard profile according to an embodiment of the present disclosure;

FIG. 11 is an illustration of an algorithm for estimating the temperature of a heated object according to an embodiment of the present disclosure;

FIGS. 12 to 14 are illustrations of use of a device for estimating the temperature of a heated object according to an embodiment of the present disclosure; and

FIG. 15 is a block diagram of a device for estimating the temperature of a heated object according to an embodiment of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of (or one or more),” when preceding a list of elements, modify the entire list of elements and do not modify the individual elements of the list.

Advantages and features of the present disclosure, as well as methods of realizing the same, will be more clearly understood from the following detailed description of embodiments when taken in conjunction with the accompanying drawings. However, it should be understood that the present disclosure is not limited to specific embodiments described hereinafter but may be embodied in a variety of different forms and include all various modifications, equivalents, and substitutions that may be included within the spirit and scope of the present disclosure. The embodiments set forth below are provided to make the description of the present disclosure complete and to fully convey the scope of the present disclosure to a person having ordinary skill in the art to which the present disclosure pertains. In the following description of the present disclosure, a detailed description of related known technology will be omitted when it is determined that the description may make the subject matter of the present disclosure rather unclear.

Terms used herein are used to describe a particular embodiment and are not intended to limit the present disclosure. Singular forms are intended to include plural forms, unless the context clearly indicates otherwise. In addition, in the present application, it should be understood that the term, such as “comprise”, “include”, or “have”, indicates that a feature, a number, a step, an operation, a component, a part or a combination thereof described in the specification is present, but does not preclude the possibility of the presence or addition of one or more other features, numbers, steps, operations, components, parts or combinations thereof in advance.

Some embodiments of the present disclosure may be represented by function block configurations and various processing steps. Some or all of these function blocks may be implemented using various numbers of hardware and/or software configurations executing specific functions. For example, the function blocks of the present disclosure may be implemented using one or more microprocessors, or may be implemented using circuit configurations for specific functions. In addition, for example, function blocks of the present disclosure may be implemented using various programming or scripting languages. Function blocks may be implemented using algorithms that run on one or more processors. In addition, the present disclosure may employ related-art technologies for electronic environment setting, signal processing, and/or data processing. Terms such as “mechanism”, “element”, “means”, and “configuration” are intended to be used broadly and are not limited to mechanical or physical configurations.

In addition, lines or members connecting components shown in the drawings merely illustrate functional connections and/or physical or circuit connections. In an actual device, components may be represented as connected by various replaceable or additional functional connections, physical connections, or circuit connections.

The present disclosure will be described in detail hereinafter with reference to the accompanying drawings.

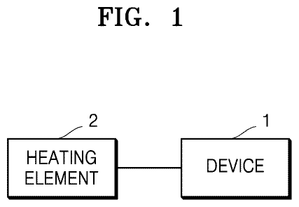

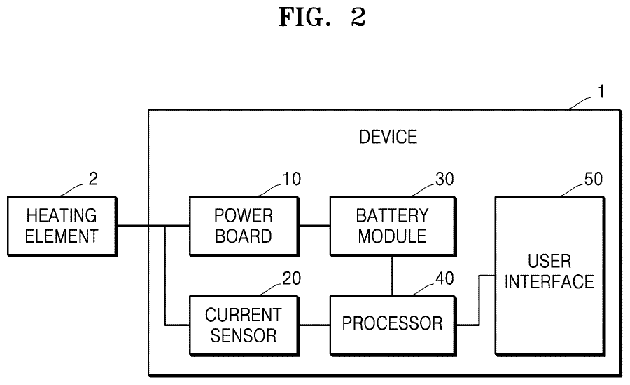

FIGS. 1 and 2 are diagrams illustrating an example of an environment for estimating the temperature of a heated object according to an embodiment of the present disclosure.

Referring to FIG. 1, the environment for estimating the temperature of a heated object includes a device for estimating the temperature of a heated object (hereinafter, referred to as “device”) 1 and a heating element 2. For example, the device 1 and the heating element 2 may be electrically connected.

FIG. 1 only shows the device 1 and the heating element 2 for ease of description, but this is not intended to be limiting. For example, other external components (not shown) or other external devices (not shown) may be included, and the operation of the device 1 described herein may be realized by a single device or a plurality of devices. In addition, the device 1 and the heating element 2 are shown in FIG. 1 as being directly connected to each other, but the device 1 and the heating element 2 may be indirectly connected by other components.

In an embodiment, the device 1 may supply power to the heating element 2 for a predetermined period of time. In an example, the device 1 may supply an initial power to the heating element 2 and obtain an initial current value corresponding to the initial power. Here, the initial current value corresponding to the initial power may mean a measured value of the current in a path along which the device 1 supplies the initial power to the heating element 2. In addition, the initial current value may mean an initial value among momentary current values corresponding to power supplied to the heating element at two or more respective points of a plurality of points in time included in the predetermined period of time.

Thereafter, the device 1 may predict the thickness of the object based on the initial current value.

In an embodiment, the device 1 may obtain a current value corresponding to power supplied to the heating element 2. Specifically, the device 1 may obtain momentary current values corresponding to the power supplied at two or more respective points of a plurality of points in time included in the predetermined period of time. In an example, the device 1 may obtain momentary current values corresponding to power supplied to the heating element 2 in real time or at predetermined intervals. The momentary current values corresponding to the power supplied to the heating element 2 may mean momentary measurement values of the current in the path along which the device 1 supplies the power to the heating element 2. Specifically, the momentary current values may be obtained using current sensors disposed on a power board configured to supply power and a conductor electrically connected to the heating element 2.

In an embodiment, the heating element may be joule heated by power. In addition, the heating element may be heated in an open loop manner where the power is controlled based on a current value.

In an embodiment, the device 1 may calculate a predetermined parameter based on the momentary current values. For example, the parameter may be a current slope, which is an amount of change in current value over time.

In an embodiment, the device 1 may use at least one of the momentary current values to determine the characteristic of the object in contact with the heating element 2. In an example, the device 1 may determine the moisture state of the object at one or more points of time included in the predetermined period of time based on the parameter calculated from the momentary current values. In this case, the moisture state includes at least one state occurring in the process of removing moisture contained in the object for the predetermined period of time. For example, the at least one state may include at least one of a first state in which the temperature of the moisture contained in the object increases, a second state in which the moisture evaporates, and a third state in which the temperature of the moisture increases. In addition, a first rate of change of the temperature of the moisture in the first state may be greater than a second rate of change of the temperature of the moisture in the third state.

In an embodiment, the device 1 may determine the moisture state to be the first state based on the result of comparing the parameter to a first threshold value. In another embodiment, the device 1 may determine a moisture state to be the second state based on the result of comparing the parameter to the first threshold value and a second threshold value less than the first threshold value. In an example, the second state may include a plurality of substates divided based on the residual moisture content of the object predicted based on the parameter. In another embodiment, the device 1 may determine the moisture state to be a third state based on the result of comparing the parameter to the second threshold value.

In an embodiment, the device 1 may estimate the temperature of the heating element 2 or the object in contact with the heating element 2 based on the parameter and the characteristic of the object. In an example, the temperature of the object may be estimated based on a temperature profile and the parameter corresponding to the thickness of the object.

Referring to FIG. 2, in an embodiment, the device 1 may include a power board 10, a current sensor 20, a battery module 30, a processor 40, and a user interface 50. However, this is only one embodiment of the modules included in the device 1, and some of these configurations may not be included, and may be components external to the device 1 rather than configurations included in the device 1.

For ease of description, the device 1 has been described throughout the description as, but is not limited to, supplying power to the heating element 2 for a predetermined period of time, obtaining momentary current values corresponding to the supplied power at two or more respective points of the plurality of points in time included in the predetermined period of time, determining the characteristic of the object in contact with the heating element 2 using at least one of the momentary current values, and estimating the temperature of the object in contact with the heating element 2 based on the parameter and the characteristic calculated based on the momentary current values. For example, at least some of the operations performed by the device 1 may be performed by another component, such as the processor 40 or a server (not shown).

In addition, for ease of description, only components relevant to the present disclosure are shown in FIG. 2. Therefore, other general purpose components may be included in the device 1 in addition to the components shown in FIG. 2. It will also be apparent to a person having ordinary skill in the art to which the present disclosure pertains that the power board 10, the current sensor 20, the battery module 30, the processor 40, and the user interface 50 shown in FIG. 2 may be implemented as independent devices.

The power board 10 may be connected to and powered by the battery module 30. That is, the power board 10 may be powered by the battery module 30. In addition, the power board 10 may supply power to the heating element 2. In this case, the power board 10 may control the power supplied to the heating element 2 by regulating a voltage level or a PWM duty of the power.

Specifically, the power board 10 may increase the power by increasing the voltage level of the power supplied to the heating element 2 and/or increasing the cycle of the PWM duty. In addition, the power board 10 may decrease the power by decreasing the voltage level of the power supplied to the heating element 2 and/or decreasing the cycle of the PWM duty. However, the control method by which the power board 10 increases or decreases the power supplied to the heating element 2 is not limited thereto.

The battery module 30 is a module to which one or more battery cells are coupled, and may provide stored electrical energy to the power board 10, i.e., the device 1. Because the device 1 is powered by the battery module 30 rather than a separate power generator, the device 1 may be implemented as a handheld device.

The processor 40 may process commands from a computer program by performing basic arithmetic, logic, and input/output operations. Here, the commands may be provided from memory (not shown) or from an external device (e.g., a server). In addition, the processor 40 may generally control the operations of other components included in the device 1. In an embodiment, the processor 40 may be a microprocessor.

The user interface 50 may receive commands from a user directing the processor 40 to perform operations corresponding to the user commands, and may output results of performing the operations. For example, the user interface 50 may include a display device. For example, the display device may be implemented as a touch screen. In another example, the user interface 50 may be connected to an independent display device by a wired or wireless communication medium to send and receive data to and from the display device. For example, the user interface 50 may receive input signals from a user and output or display at least one of the momentary current values, the characteristic of the object, the parameter calculated based on the momentary current values, the temperature of the object in contact with the heating element 2, and the thickness of the object.

The user interface 50 may be an input/output interface. For example, the user interface 50 may be a means for interfacing with an input or output device (e.g., a keyboard or a mouse) that may be connected to or included in a user terminal (not shown). The user interface 50 may be configured separately from the processor 40, but is not limited thereto, and the user interface 50 may be configured to be included in the processor 40.

The current sensor 20 is a device that measures the amount of current flowing through an electrical circuit, and in an embodiment, the current sensor 20 may be disposed on an electrical wire electrically connecting the power board 10 and the heating element 2 to each other. Accordingly, the current sensor 20 may measure the value of a current (which may include an initial current corresponding to an initial power) corresponding to the power. The current sensor 20 may transmit the measured current value to the processor 40.

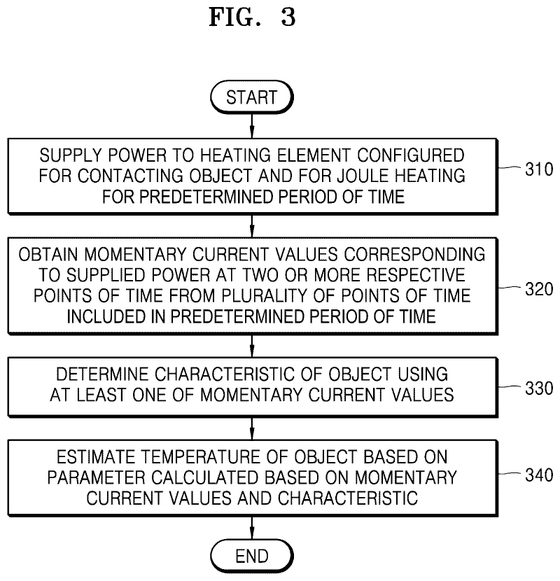

FIG. 3 is a flowchart illustrating a method of estimating the temperature of a heated object according to an embodiment of the present disclosure.

Referring to FIG. 3, in operation 310, the device may supply power to the heating element for a predetermined period of time.

In an embodiment, the heating element may contact the object and generate heat by joule heating.

In operation 320, the device may obtain momentary current values corresponding to power supplied at two or more respective points of the plurality of points in time included in the predetermined period of time.

In an embodiment, the momentary current values corresponding to the power supplied to the heating element may refer to measured values of current flowing through an electrical wire that directly and electrically connects the device and the heating element. Specifically, the device may obtain the current values corresponding to the power supplied to the heating element by obtaining current values measured by a current sensor disposed on the electric wire electrically connecting the device (in particular, the power board) and the heating element to each other.

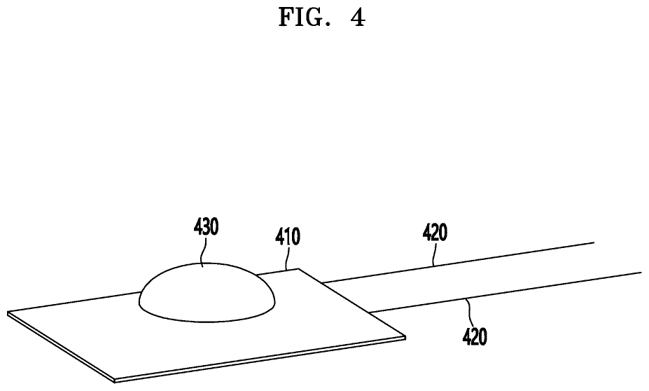

FIG. 4 is an example diagram illustrating an object in contact with a heating element according to an embodiment of the present disclosure.

Referring to FIG. 4, an object 430 is shown in contact with a heating element 410.

As described above, a momentary current value corresponding to power supplied to the heating element 410 may refer to a current value flowing through the electrical wire 420 electrically connecting the device and the heating element 410 to each other. In addition, the device may obtain the current value corresponding to the power supplied to the heating element 410 by obtaining a current value measured by a current sensor (not shown) disposed on the electrical wire 420 electrically connecting the device and the heating element 410 to each other.

A plurality of electrical wires 420 electrically connecting the device and the heating element 410 to each other are shown in FIG. 4, but the number of electrical wires 420 is not limited thereto, and a single electrical wire may be provided.

In an embodiment, the heating element 410 may be a material that generates heat due to the resistance of the element itself when current passes therethrough. In an example, the heating element 410 may be a ceramic heating element.

The ceramic heating element is a heating element used to convert supplied power, or electrical energy, into heat. Ceramic materials may provide electrical safety due to high thermal resistance and electrical insulation properties, and in particular may generate a lot of heat at relatively low power or current due to high resistance of the ceramic materials themselves. In addition, the ceramic heating element may have positive temperature coefficient (PTC) properties, which allow the ceramic heating element to self-regulate the temperature thereof by increasing the resistance thereof as the temperature increases. Accordingly, forming the heating element 410 from a ceramic material may increase energy efficiency and prevent overheating.

In an embodiment, the heating element 410 may be joule heated by power.

Joule heat means heat generated by the conversion of electrical energy to thermal energy by the electrical resistance of the heating element 410 when current flows through the heating element 410. That is, when the heating element 410 is powered, thermal energy may be generated by the electrical resistance of the element itself. Then, the heating element 410 may generate an amount of heat that is proportional to the square of the current. Accordingly, the device may estimate the temperature of the heating element 410 or the object in contact with the heating element 410 using the current value corresponding to the power supplied to the heating element 410.

In addition, the object 430 is shown in FIG. 4 as a water droplet, i.e., moisture, but the type of the object 430 is not limited thereto, and the object 430 may or may not contain water.

In an embodiment, the heating element 410 may be heated in an open loop manner, where the power is controlled based on the momentary current value. The open loop heating method is a method of heating by simply applying power, rather than a closed loop method of measuring conditions such as the temperature of the heating element 410 or the object 430 and using the conditions as feedback. That is, the power supplied to the heating element 410 may be controlled only by the momentary current value obtained from the current sensor. Therefore, the cost of heating the object is low because a separate temperature measurement sensor or the like is not required; however, due to the lack of feedback, it is difficult to accurately maintain a heating target value, and how to estimate the temperature of the object is problematic.

In an embodiment, the device may determine the characteristic of the object 430 and estimate the temperature of the object based on the characteristic. Returning to FIG. 3, in operation 330, the device may determine the characteristic of the object using at least one of the momentary current values.

In an embodiment, the device may calculate a parameter from the momentary current values. For example, a rate of change of the current value over time may be calculated using the parameter. Hereinafter, the rate of change of the current value over time is referred to as the current slope, which indicates how quickly the current value changes over time.

In an example, when the current value over time is represented by a function I (t), the device may calculate the derivative of the current value I(t) over time t as the current slope. In another example, the device may calculate the current slope by dividing a change in current value over a predetermined sampling time (e.g., 10 ms) by the sampling time. In another example, the device may graph the current value changing over time, approximate the graph to a linear function, and calculate the slope of the linear function as the current slope. However, the method by which the device calculates the current slope using the change in current value over time is not limited thereto. The current slope may have a unit of A/s.

In an embodiment, the device may determine a moisture state of the object 430 at one or more points in time included in a predetermined period of time based on the parameter calculated from the momentary current values. That is, any of the above-described characteristics of the object may include the moisture state of the object 430.

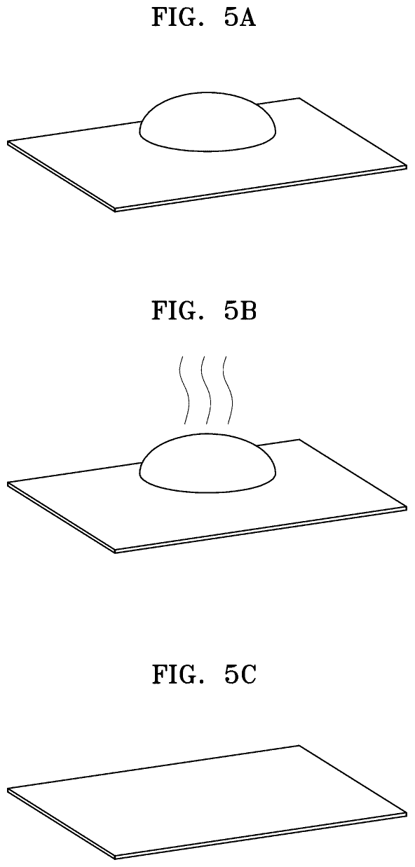

FIGS. 5A to 5C are diagrams illustrating a moisture state of an object according to an embodiment of the present disclosure.

In an embodiment, the moisture state may include at least one state occurring in the process of removing moisture contained in the object over a predetermined period of time. For ease of description, FIGS. 5A to 5C show a water droplet, i.e., moisture, in contact with the heating element, but the following description may be applied to any object that contains moisture.

Referring to FIG. 5A, a first state in which the temperature of the moisture increases is shown.

In an embodiment, the moisture state may include a first state. The first state is an initial step necessary for the moisture to evaporate, including a state in which the moisture is heated and the temperature of the moisture increases. Specifically, in the first state, the water molecules of the moisture may be supplied with thermal energy to increase the kinetic energy thereof. In this case, the heat source may be a heating element.

Referring to FIG. 5B, a second state in which the moisture evaporates is shown.

In an embodiment, the moisture state may include a second state. The second state includes a state in which the water molecules of the moisture are heated and have sufficient kinetic energy to evaporate from a liquid state to a gaseous state and move into the air. Specifically, the water molecules of the moisture in the second state may receive sufficient thermal energy from the heat source to overcome the surface tension of the liquid and escape from the surface of the liquid.

In an embodiment, the water in the second state may experience a temperature drop due to the latent heat of evaporation. The latent heat of evaporation is thermal energy that water molecules absorb to change from a liquid state to a gaseous state. For example, the latent heat of evaporation of water is 2260 KJ/kg. Since the latent heat of evaporation of the water in the second state is generated, the current slope corresponding to the object in the second state may only exhibit a constant value or a change within a predetermined range. That is, since most of the thermal energy supplied by the heating element, which is the heat source, contributes to the latent heat of evaporation of the water in the second state, the water in the second state has no or a small a temperature change, and the current slope has no or a slowed down change, so that the current slope may only change within a predetermined range.

Referring to FIG. 5C, a third state in which the temperature of the moisture increases is shown.

In an embodiment, the moisture state may include a third state. The third state includes a state in which all or most of the moisture in the object has evaporated. Accordingly, the power (or current) required to increase the temperature of the object in the third state is lower than in the first state. As a result, the second rate of change of the temperature of the moisture in the third state may be lower than the first rate of change of the temperature of the moisture in the first state. On the other hand, continuously supplying the power to the object in the third state may change the physical and/or chemical properties of the object. That is, by adjusting the time to supply the power to the object in the third state, the object may be heated until the object has the desired physical and/or chemical properties.

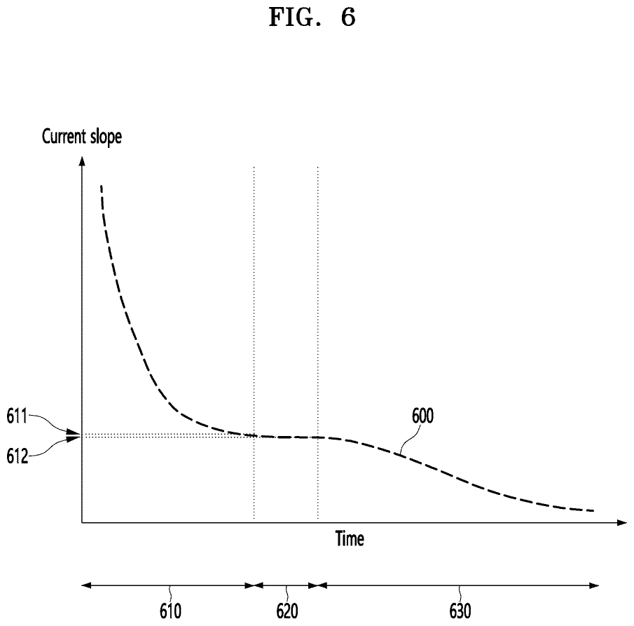

FIG. 6 is a diagram illustrating a current slope according to an embodiment of the present disclosure.

In an embodiment, the device may determine moisture states 610, 620, and 630 of an object in contact with a heating element based on a current slope 600.

Referring to FIG. 6, an aspect in which the current slope 600 decreases as the object dehydrates may be seen. Specifically, when the device supplies power to the heating element in contact with the object, an initial current value is determined by the initial impedance of the object. At this time, the impedance of the object increases as moisture evaporates from the object in response to the moisture removal process, and the rate of change of the impedance of the object decreases according to the time series.

In an embodiment, the device may determine the moisture state of the object in contact with the heating element to be one of the first to third states 610, 620, and 630 based on a current slope 600.

In an example, the device may determine the moisture state to be the first state 610 based on a result of comparing the current slope 600 and the first threshold value 611. Specifically, the device may determine the moisture state to be the first state 610 when the current slope 600 is greater than or equal to the first threshold value 611. That is, when the object has a rate of change of the current value greater than the first threshold value 611, the device may determine the moisture state to be the first state 610 in which the temperature increases so that the moisture in the object evaporates.

In another example, the device may determine the moisture state to be the second state 620 based on a result of comparing the current slope 600 to the first threshold value 611 and the second threshold value 612. Specifically, the device may determine the moisture state to be the second state 620 when the current slope 600 is less than the first threshold value 611 and equal to or greater than the second threshold value 612. In this case, as shown in FIG. 6, the second threshold value 612 may be a value less than the first threshold value 611. The object in the first state 610 has an increase in impedance as the temperature increases, and when the current slope 600 is less than the first threshold value 611, the device may determine that the moisture in the object has begun to evaporate and determine the moisture state to be the second state 620. Referring to FIG. 6, the current slope 600 of the object in the second state 620 may only exhibit a constant value or a change within a predetermined range due to the latent heat of evaporation. Accordingly, for example, when the change in the current slope 600 is less than a certain percentage (e.g., 5%), the device may determine the moisture state to be the second state 620. The change in the current slope 600 is the rate of change of the current slope 600 over time, and the same embodiment as the previous embodiment of calculating the rate of change of the current value over time may be applied.

In another example, the device may determine the moisture state to be the third state 630 based on a result of comparing the current slope 600 and the second threshold value 612. Specifically, the device may determine the moisture state to be the third state 630 when the current slope 600 is less than the second threshold value 612. That is, when the moisture in the object has completely evaporated through the second state 620, the impedance of the object may rise sharply and the current slope 600 may fall. Accordingly, the device may determine the moisture state to be the third state 630 when the current slope 600 is below the second threshold value 612.

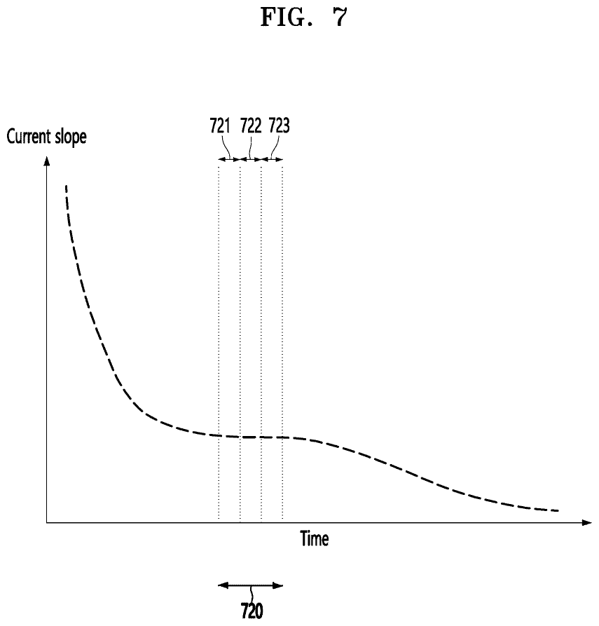

FIG. 7 is a diagram illustrating a plurality of substates according to an embodiment of the present disclosure.

Referring to FIG. 7, a second state 720 of an object may be divided into a plurality of substates 721, 722, and 723. Specifically, the second state 720 may include the plurality of substates 721, 722, and 723 that are divided based on the residual moisture content of the object.

At this time, the residual moisture content of the object may be predicted based on the current slope. The second state 720 is a state in which the moisture in the object evaporates, and the impedance may vary depending on the residual moisture content of the object. Here, the current slope of the second state 720 may only exhibit a constant value or a change within a predetermined range.

Accordingly, in an example, the device may divide the second state 720 into a plurality of substates 721, 722, and 723 by predicting the moisture content of the object based on the current slope of the first state 710 and calculating the predicted duration of the second state 720 based on the predicted moisture content. For example, when the predicted duration of the second state 720 is three seconds, the device may divide the second state 720 into the three substates 721, 722, and 723 having one-second intervals. However, the method by which the device divides the second state into a plurality of substates 721, 722, and 723 is not limited thereto, and the number of the substates 721, 722, and 723 is not limited to three.

Referring to FIG. 3, in operation 340, the device may estimate the temperature of the object based on the parameter calculated based on the momentary current values and the characteristic of the object. In this case, the parameter calculated based on the momentary current values may represent the current slope.

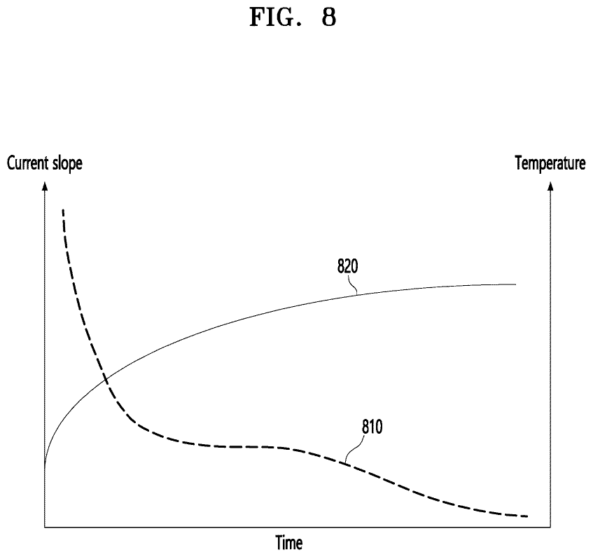

FIG. 8 is a diagram illustrating a current slope and an estimated temperature according to an embodiment of the present disclosure.

In an embodiment, the device may estimate a temperature 820 of an object based on the characteristic and parameter of the object. Specifically, the device may estimate the temperature 820 of the object based on a current slope 810.

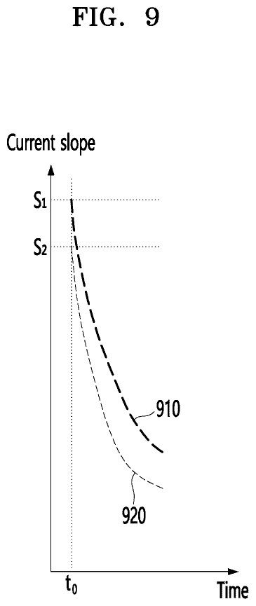

In an embodiment, the characteristic of the object may include the thickness of the object. In an example, the device may predict the thickness of the object based on an initial current value corresponding to initial power supplied to the heating element. Specifically, the device may predict the thickness of the object based on an initial impedance of the object based on the initial current value, and may estimate the temperature of the object based on the predicted thickness of the object. For example, the device may estimate the temperature 820 of the object using a temperature profile corresponding to the thickness of the object. In this case, the temperature profile may be a profile representing the temperature 820 of the object along the current slope 810, and may be predetermined based on the thickness of the object. This will be described in more detail below with reference to FIGS. 9.

In another embodiment, the device may calculate a power value over time by integrating the acquired current values, and may calculate an amount of energy by integrating the power value again. In this case, the device may predict the specific heat of the object based on at least one of the thickness and the impedance of the object predicted based on the initial current value. Thereafter, the device may predict changes in the temperature 820 of the object based on the amount of energy and the specific heat of the object.

That is, the device may predict the moisture state of the object and estimate the temperature 820 of the object based on the current slope 810, and may therefore be used in various industrial fields.

FIG. 9 is a diagram illustrating a method of selecting a standard profile according to an embodiment of the present disclosure.

In an embodiment, the device may select a temperature profile corresponding to the thickness of an object.

Specifically, the device may supply initial power to the heating element. The initial power may refer to an initial value of power supplied to the heating element. Thereafter, the device may obtain an initial current value corresponding to the initial power. The initial current value may mean a first value among momentary current values obtained during a predetermined period of time as described above. In addition, the initial current value corresponding to the initial power may mean a measured value of current flowing through an electrical wire directly connecting the device and the heating element. Specifically, the device may obtain the initial current value corresponding to the initial power supplied to the heating element by obtaining a current value measured by a current sensor disposed on an electrical wire electrically connecting the device and the heating element to each other.

In an embodiment, the device may predict the thickness of the object based on the initial current value. For example, a thicker thickness of the object may exhibit a lower current value due to higher impedance, and in contrast, a thinner thickness of the object may exhibit a higher current value due to lower impedance. Therefore, the device may calculate the impedance from the obtained initial current and predict the thickness of the object based on the impedance.

Referring to FIG. 9, a current slope 910 of a first object having an initial current value S1 at to and a current slope 920 of a second object having an initial current value S2 at to are shown. According to the foregoing description, since the initial current value S1 of the first object is higher than the initial current value S2 of the second object, the device may predict the thickness of the first object to be thinner than the thickness of the second object.

In an embodiment, the device may select a temperature profile corresponding to the predicted thickness of the object. The temperature profile may be a profile representing the temperature of the object according to the current slope, and may be predetermined according to the thickness of the object. That is, temperature profiles corresponding to the respective thicknesses of the object are predetermined, and the device may select one of the temperature profiles corresponding to the predicted thickness of the object. Accordingly, the device may estimate the temperature of the object according to the current slope of the object.

In an embodiment, the device may control power based on the moisture state of the object. Specifically, the device may perform power control to increase, decrease, or maintain the power by controlling at least one of the voltage level and the PWM duty of the power based on the moisture state.

In an embodiment, the device may determine the power supplied to the heating element based on the standard profile, and may control the power based on the moisture state of the object and the current slope. In this case, the standard profile may mean a profile of a current slope expected based on the initial current value and the predicted thickness of the object. Thereafter, the device may determine the power supplied to the heating element based on the standard profile.

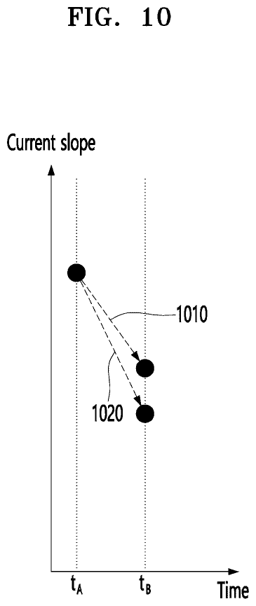

FIG. 10 is a diagram illustrating a method of controlling power based on a standard profile according to an embodiment of the present disclosure.

In an embodiment, the device may calculate a change in current slope 1010 over time. Since a current slope is an amount of change in a current value over time, the change in current slope 1010 may be an amount of change in the current slope over time. Therefore, the method by which the device calculates the current slope may be used in the method by which the device calculates the change in current slope 1010.

In an embodiment, the device may increase or decrease power based on the change in current slope 1010 that differs from a standard profile 1020 by a predetermined value or more. That is, when it is determined that the current does not exhibit a current slope similar to the standard profile 1020 even after a predetermined period of time, the device may increase or decrease the power. For example, as shown in FIG. 10, when the change in current slope 1010 is not as sharp as compared to the standard profile 1020, the change in current slope 1010 indicates that the process of removing moisture from the object is progressing more slowly than expected, and therefore the device may increase the power.

Similarly, although not shown in FIG. 10, when the change in current slope 1010 is sharp compared to the standard profile 1020, the change in current slope 1010 indicates that the process of removing moisture from the object is progressing faster than expected, and therefore the device may reduce the power.

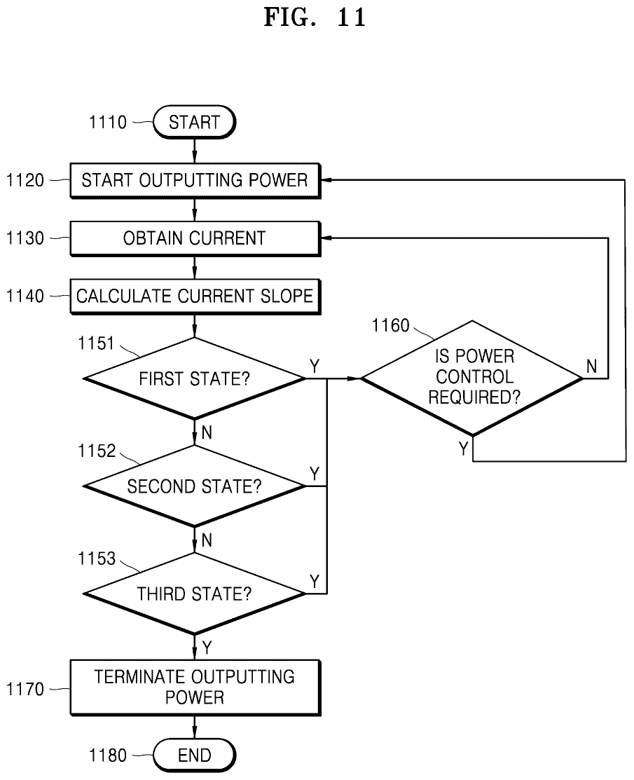

FIG. 11 is an illustration of an algorithm for supplying power to a heated object according to an embodiment of the present disclosure.

In an embodiment, the device may be activated based on an actuation signal from a user. In response, in 1110, the device initiates an algorithm to supply power to the heating element.

In an embodiment, in 1120, the device outputs power to the heating element. In an example, in 1120, the device may output initial power to the heating element. In another example, in 1120, the device may output controlled (i.e., increased or decreased) power to the heating element for a predetermined period of time.

In an embodiment, in 1130, the device may obtain a momentary current value corresponding to the power supplied to the heating element over a predetermined period of time. In addition, in 1140, the device may calculate a change in current value over time, i.e., a current slope.

In an embodiment, the device may determine the characteristic of an object contacted by the heating element based on the current slope. In an example, the device may determine the moisture state of the object. At this time, the device may determine whether power control is required based on the moisture state in 1160. In an embodiment, the device may control the power based on the result of the determination in 1160.

In an example, the device may determine whether the moisture state of the object is a first state in 1151, when the moisture state of the object is determined to be the first state, determine whether the moisture state of the object requires the power control in 1160, and when the moisture state of the object is determined not to be the first state, determine whether the moisture state of the object is a second state in 1152. In another example, the device may determine whether the moisture state of the object is the second state in 1152 and, when the moisture state of the object is determined to be the second state, determine whether the power control is required in 1160. In another example, the device may determine whether the moisture state of the object is a third state in 1153 and, when the moisture state of the object is determined not to be the third state, determine whether the power control is required in 1160. For example, the device may determine 1160 whether the power control is required based on a standard profile.

In an embodiment, when it is determined that the power control is required, the device may return to the operation 1120 to output controlled power to the heating element. In contrast, when it is determined that the power control is not required, the device may return to the operation 1130 to obtain a current corresponding to the power supplied to the heating element.

As described above, the device may repeat the operations described above until the moisture state is determined to be a predetermined target state. Specifically, the device may repeat the operations of obtaining the current in 1130, calculating the current slope in 1140, determining the moisture state in 1151, 1152, and 1153, determining whether the power control is required in 1160, and controlling the power or outputting the controlled power in 1120.

In an embodiment, in response to determining the moisture state of the object to be the predetermined target state, the device may terminate the supply of the power in 1170. In an example, when the device determines that the moisture state of the object is the third state, the device may terminate the supply of the power 1170. However, the predetermined target state being the third state is only an embodiment, and is not limited thereto. For example, the predetermined target state may be one of the plurality of substates included in the second state.

In an embodiment, upon termination of the supply of the power in 1170, the device terminates the algorithm for supplying power to a heating element in 1180.

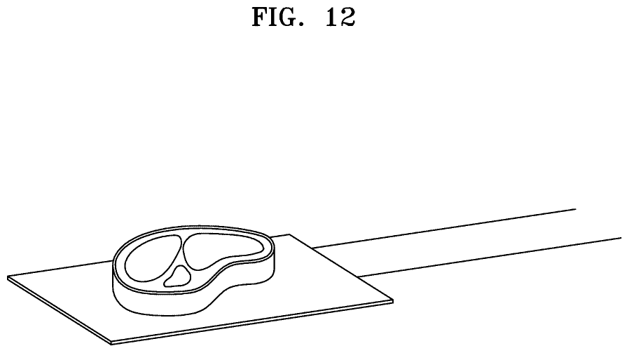

FIGS. 12 to 14 are illustrations of use of a device for estimating the temperature of a heated object according to an embodiment of the present disclosure.

Referring to FIG. 12, the object may be a food. In this case, the device may power the heating element, obtain momentary current values until the moisture state of the food reaches a target state specified by a user, determine the moisture state of the food based on a current slope, and estimate the temperature of the food based on the moisture state. For example, the target state specified by the user may be one of the plurality of substates included in the second state.

In an embodiment, when the food, which is the object, is a beef steak, the user may specify the target state based on a desired degree of doneness of the beef steak, and the device may supply power to the heating element until the target state is determined to be the target state specified by the user. At this time, the beef steak may be cooked until the temperature is increased by contact with the heating element and the state of the moisture including blood inside the beef steak reaches the target state, and accordingly, the heating may be stopped at the desired degree of doneness without directly contacting the food with a thermometer or using a separate temperature sensor.

On the other hand, when the object is food, the heating element receiving power from the device may include one or two heating elements. When the device includes a single heating element, the device may heat one side of the food, and when the device includes two heating elements, the device may heat opposite sides of the food at the same time.

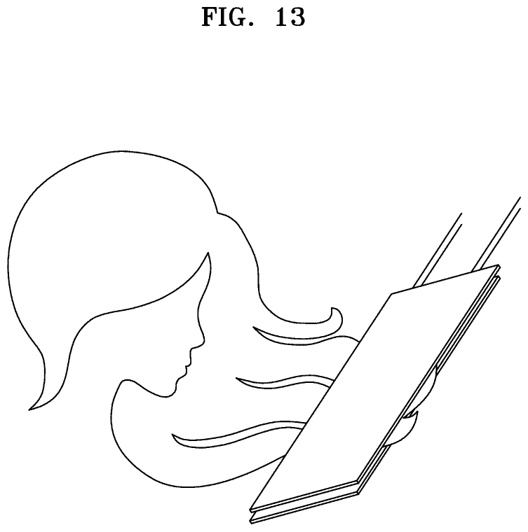

Referring to FIG. 13, the object may be a hair. In this case, the device may supply power to the heating element, obtain momentary current values until the moisture state of the hair reaches a target state specified by a user, determine the moisture state of the hair based on a current slope, and estimate the temperature of the hair based on the moisture state. For example, the target state specified by the user may be one of the plurality of substates included in the second state and the third state.

In an embodiment, the user may specify the target state based on a degree of hair styling for the hair, which is the object, and the device may supply the power to the heating element until the target state specified by the user is reached. At this time, the temperature of the hair may be increased by contact with the heating element, and the hair may be deformed by the heat until the internal moisture state thereof reaches the target state, thereby allowing the hair styling to be performed only at the temperature desired by the user without further damage to the hair.

On the other hand, when the object is hair, the heating element powered by the device may include two heating elements.

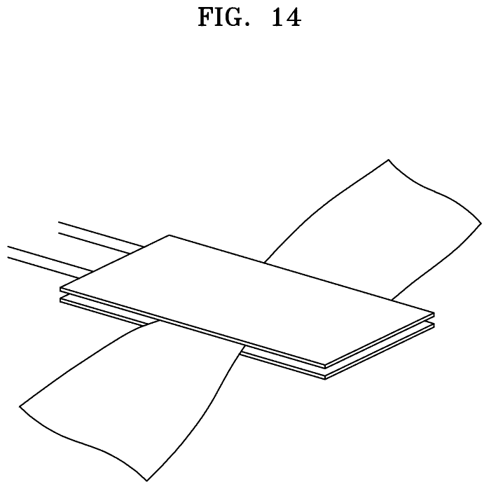

Referring to FIG. 14, the object may be a blood vessel. In this case, the device may supply power to the heating element, obtain a current value until the moisture state of the blood vessel reaches a target state specified by a user, determine the moisture state of the blood vessel based on a current slope, and estimate the temperature of the blood vessel based on the moisture state. For example, the target state specified by the user may be the third state.

In an embodiment, the user may specify the target state based on a desired degree of deformation of the blood vessel, and the device may supply power to the heating element until the target state specified by the user is reached. At this time, the temperature of the blood vessel may be increased by contact with the heating element, and the blood vessel may be deformed until the state of the moisture including blood inside the blood vessel reaches the target state. That is, the walls of the blood vessel may be bonded together due to collapsing (or melting) of the protein structure in the blood vessel and the water in the blood vessel may be reduced, thereby causing the walls of the blood vessel to coalesce and the blood vessel to be sutured. Accordingly, the vessel may be sutured safely without the use of a separate temperature sensor.

On the other hand, when the object is the blood vessel, the heating element powered by the device may include one or two heating elements. When the device includes a single heating element, the device may heat one side of the blood vessel, and when the device includes two heating elements, the device may heat opposite sides of the blood vessel at the same time. Here, even in the case where the device includes a single heating element, an additional jaw may be provided for suturing the blood vessel. That is, the device may include two jaws for applying pressure to the blood vessel, in which only one of the jaws may be the heating element.

FIGS. 12 to 14 are example embodiments in which the device for estimating the temperature of a heated object may be used, but are not intended to be limiting.

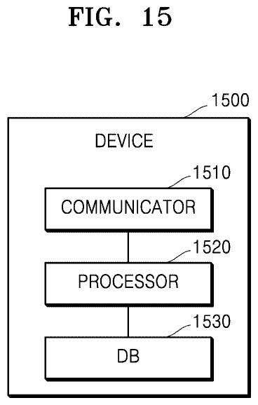

FIG. 15 is a block diagram of a device for estimating the temperature of a heated object according to an embodiment of the present disclosure.

Referring to FIG. 15, a device 1500 may include a communicator 1510, a processor 1520, and a database (DB) 1530. The device 1500 of FIG. 15 only shows the components according to the embodiment. Accordingly, it will be understood by a person having ordinary skill in the art that general purpose components other than those shown in FIG. 15 may be further included.

In addition, the device 1500 of FIG. 15 may refer to a computing device that is the same as or included in the device 1 shown in FIG. 1 or 2.

The communicator 1510 may include one or more components that enable wired or wireless communication with an external server or an external device. For example, the communicator 1510 may include at least one of a local area communicator (not shown), a mobile communicator (not shown), and a broadcast receiver (not shown).

The DB 1530 is hardware that stores various data processed within the device 1500, and may store programs for processing and controlling the processor 1520.

The DB 1530 may include random access memory (RAM), such as dynamic random access memory (DRAM) or static random access memory (SRAM), read-only memory (ROM), electronically erasable programmable read-only memory (EEPROM), a CD-ROM, Blu-ray or other optical disk storage, a hard disk drive (HDD), a solid state drive (SSD), or flash memory.

The processor 1520 controls the overall operation of the device 1500. For example, the processor 1520 may control the overall operation of an input (not shown), a display (not shown), the communicator 1510, the DB 1530, and the like by executing the programs stored in the DB 1530. The processor 1520 may control the operation of the device 1500 by executing the programs stored in the DB 1530.

The processor 1520 may control at least some of the operations of the device described above with reference to FIGS. 1 to 14.

The processor 1520 may be implemented using at least one of an application specific integrated circuit (ASICs), digital signal processors (DSPs), digital signal processing devices (DSPDs), programmable logic devices (PLDs), field programmable gate arrays (FPGAs), controllers, microcontrollers, microprocessors, and other electrical units for performing functions.

In an embodiment, the device 1500 may be a server. The server may be implemented as a computing device or a plurality of computing devices that communicate over a network to provide commands, code, files, content, services, and the like. The server may receive data or command signals necessary to estimate the temperature of the heated object, and may estimate the temperature of the heated object based on the data or command signals received.

Embodiments according to the present disclosure may be implemented in the form of a computer program that may be executed by various components on a computer, and such a computer program may be recorded on a computer-readable medium. Here, the medium may include magnetic media such as hard disks, floppy disks, and magnetic tape, optical recording media such as compact disc read-only memories (CD-ROMs) and digital versatile discs (DVDs), magneto-optical media such as floptical disks, and hardware devices specially configured to store and execute program instructions, such as ROM, RAM, flash memory, and the like.

In addition, the computer program may be specially designed and configured for the present disclosure, or may be known and available to a person having ordinary skill in the art of computer software. Examples of computer programs may include machine language code, such as that produced by a compiler, as well as high-level language code that may be executed by a computer using an interpreter or the like.

According to an embodiment, methods according to various embodiments of the present disclosure may be provided as included in a computer program product. The computer program product is a commodity, and may be traded between a seller and a buyer. The computer program product may be distributed in the form of a device-readable storage medium (e.g., a CD-ROM), or may be distributed online (e.g., downloaded or uploaded) through an application store (e.g., Play Store™) or directly between two user devices. In the case of online distribution, at least a portion of the computer program product may be stored or at least temporarily generated on a device-readable storage medium, such as a memory of a manufacturer's server, an application store's server, or a relay server.

Unless explicitly stated herein or otherwise, the steps of the method according to the present disclosure may be performed in any suitable order. The present disclosure is not necessarily limited to the order in which the steps are described above. The use of any examples or illustrative terms (e.g., such as) herein is only for the purpose of describing the present disclosure in detail and the scope of the present disclosure is not limited to the examples or illustrative terms unless defined by the claims. In addition, a person having ordinary skill in the art will appreciate that various modifications, combinations, and alterations are possible depending on the design conditions and factors within the scope of the appended claims or equivalents thereof.

Therefore, it should be understood that the spirit of the present disclosure is not limited to the foregoing embodiments, and the scope of the appended claims, as well as all scopes equivalent to or equivalently modified from the scope of the claims, are included within the scope of the spirit of the present disclosure.

The present disclosure as set forth above enables the effect of indirectly controlling the temperature of the heating element only using a change in current depending on the moisture content of the heating element.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of estimating a temperature of a heated object, the method comprising:
supplying power to a heating element for a predetermined period of time, the heating element being configured for contacting an object and for joule heating;
obtaining momentary current values corresponding to the power at two or more respective points of time from a plurality of points of time included in the predetermined period of time;
determining a characteristic of the object using at least one of the momentary current values; and
estimating a temperature of the object based on a parameter calculated based on the momentary current values and the characteristic.

2. The method of claim 1,
wherein the determining comprises
determining a moisture state of the object at one or more points of time included in the predetermined period of time based on the parameter calculated based on the momentary current values.

3. The method of claim 2,
wherein the moisture state comprises
at least one state occurring during a process of removing moisture contained in the object for the predetermined period of time.

4. The method of claim 3,
wherein the at least one state comprises
at least one of a first state in which a temperature of moisture contained in the object increases, a second state in which the moisture evaporates, and a third state in which the temperature of the moisture increases, and
wherein a first rate of change of the temperature of the moisture in the first state is greater than a second rate of change of the temperature of the moisture in the third state.

5. The method of claim 4,
wherein the determining comprises
determining the moisture state to be the first state based on a result of comparing the parameter to a first threshold value.

6. The method of claim 4,
wherein the determining comprises
determining the moisture state to be the second state based on a result of comparing the parameter to a first threshold value and a second threshold value, and
the second threshold value is smaller than the first threshold value.

7. The method of claim 4,
wherein the determining comprises
determining the moisture state to be the third state based on a result of comparing the parameter to a second threshold value.

8. The method of claim 4,
wherein the second state comprises
a plurality of substates divided based on a residual moisture content of the object predicted based on the parameter.

9. The method of claim 1,
wherein the heating element is
heated in an open loop manner where the power is controlled based on the momentary current values.

10. The method of claim 1,
wherein the determining comprises
predicting a thickness of the object based on an initial value of the momentary current values.

11. The method of claim 10,
wherein the predicting comprises
estimating a temperature of the object based on a temperature profile corresponding to the thickness of the object and the parameter.

12. The method of claim 1,
wherein the momentary current values are
obtained using a current sensor disposed on an electrical wire electrically connecting a power board configured to supply the power and the heating element to each other.

13. A device for estimating a temperature of a heated object, the device comprising:
a memory having at least one program stored therein; and
a processor configured to perform calculation by executing the at least one program,
wherein the processor is configured to
supply power to a heating element for a predetermined period of time, the heating element being configured for contacting an object and for joule heating, obtain momentary current values corresponding to the power at two or more respective points of time from a plurality of points of time included in the predetermined period of time, determine a characteristic of the object using at least one of the momentary current values, and estimate a temperature of the object based on a parameter calculated based on the momentary current values and the characteristic.

14. A computer-readable recording medium having recorded thereon a program to cause a computer to execute the method of claim 1.
